(19) United States
(12) Patent Application Publication
(10) Pub. No.: US 2014/0331709 A1
(43) Pub. Date: Nov. 13, 2014

(54) COOLING DEVICE AND ELECTRONIC DEVICE USING THE SAME

(71) Applicant: NEC Corporation, Tokyo (JP)

(72) Inventors: Masaki Chiba, Tokyo (JP); Minoru Yoshikawa, Tokyo (JP); Hitoshi Sakamoto, Tokyo (JP); Akira Shoujiguchi, Tokyo (JP); Kenichi Inaba, Tokyo (JP); Arihiro Matsunaga, Tokyo (JP)

(21) Appl. No.: 14/370,190

(22) PCT Filed: Dec. 12, 2012
(86) PCT No.: PCT/JP2012/007941

§ 371 Date: Jul. 1, 2014

(30) Foreign Application Priority Data
Jan. 4, 2012 (JP) 2012-000039

(51) Int. Cl. H05K 7/20; F25B 39/00; F25B 39/04; F28D 15/02; F25B 39/02

(52) U.S. Cl. CPC H05K 7/2029; F28D 15/02; F25B 39/02; F25B 39/04; F25B 39/00; H05K 7/20309; H05K 7/20318
USPC 62/404; 165/59

(57) ABSTRACT

When a cooling device employing an ebullient cooling system is mounted in a low-profile electronic device, not only is it impossible to obtain the sufficient cooling performance, but also the cooling efficiency of the entire electronic device decreases, therefore, a cooling device according to an exemplary aspect of the invention includes evaporating means for storing a refrigerant; condensing means for condensing and liquefying a vapor-phase refrigerant vaporized in the evaporation means and radiating heat; a pipe connecting the evaporating means to the condensing means; and flow regulating means for regulating a flow direction of air passing through the condensing means, wherein the evaporating means and the condensing means are located on roughly the same level in the vertical direction; the evaporating means includes an evaporation container and bulkhead means for separating the refrigerant disposed in the evaporation container; the height of the bulkhead means is larger than or equal to the height of a vapor-liquid interface of the refrigerant and is smaller than the height of the evaporation container; the pipe includes a vapor pipe through which vapor-phase refrigerant flows and a liquid pipe through which condensed and liquefied liquid-phase refrigerant flows; the condensing means includes first condensing means and second condensing means which differ in condensing-means height which is defined as the height in vertical direction of a condensation container composing the condensing means, and the condensing-means height of the first condensing means is configured to be larger than the condensing-means height of the second condensing means; the first condensing means includes a vapor pipe connection portion which is connected to the vapor pipe at the position above the condensing-means height of the second condensing means in vertical direction; and the flow regulating means is disposed in the upper part of the second condensing means.

### TECHNICAL FIELD

The present invention relates to cooling devices for semiconductor devices, electronic equipment and the like and, in particular, to a cooling device and an electronic device using the same employing an ebullient cooling system in which heat transport and heat radiation are performed by a phase-change cycle of vaporization and condensation of a refrigerant.

### BACKGROUND ART

In recent years, with the progress of high performance and high functionality in semiconductor devices, electronic equipment and the like, the amount of heat generation from them has also been increasing. There has been a problem, therefore, that the cooling performance degrades due to a dryout of the operating fluid in the cooling device using a heat pipe in which the operating fluid is circulated by capillary force. In contrast, it is possible to improve the heat transport capability for the cooling device employing the ebullient cooling (thermosiphon) system in which heat transport and heat radiation are performed using the circulation by a phase-change cycle of vaporization and condensation of a refrigerant and the gravity because the refrigerant moves in a state of a gas-liquid two-phase flow. Therefore, it has been expected as a cooling device used for semiconductor devices, electronic equipment and the like with large amount of heat generation.

An example of the cooling device employing the ebullient cooling system (hereinafter, also referred to as “an ebullient cooling device”) is described in Patent Literature 1. FIG. 13 is a cross-sectional side view illustrating a configuration of the related ebullient cooling device 500 described in Patent Literature 1. The related ebullient cooling device 500 is used for cooling a semiconductor device 502 as a heat generation source such as a CPU which is mounted on a circuit board 501. The related ebullient cooling device 500 includes an evaporating portion 510 attached on the surface of the semiconductor device 502 and a condenser 520 having a radiator, between which a pair of conduits composed of a vapor conduit 531 and a liquid return conduit 532 are attached. Here, the related ebullient cooling device 500, whose inside is maintained to be a reduced (low) pressure condition of approximately one-tenth of the atmospheric pressure, composes a thermosiphon which enables the refrigerant liquid to circulate without any external power source such as an electric pump by the phase change of water of a liquid refrigerant.

In the related ebullient cooling device 500, the heat generated in the semiconductor device 502 as a heat generation source is transferred to the evaporating portion 510. As a result, the water (Wa) of a liquid refrigerant boils and evaporates by the transferred heat under reduced pressure in the evaporating portion 510, and the generated steam (ST) is conducted from the evaporating portion 510 to the condenser 520 through the vapor conduit 531. In the condenser 520, the refrigerant vapor is cooled by the air (AIR) blown by a cooling fan 540 or the like and becomes liquid (water), which then is circulated again by the gravity to the evaporating portion 510 through the liquid return conduit 532.

Here, the condenser 520 includes a plurality of flat tubes, on which inner wall surfaces a large number of fine grooves are formed. It is said that above-mentioned configuration makes it possible to improve a condensing heat transfer coefficient, to improve the performance of the condenser 520, and therefore to cool the heat generation from a heating element at low cost and efficiently.

### CITATION LIST

### Patent Literature

Patent Literature 1: Japanese Patent Application Laid-Open Publication No. 2011-047616 (paragraphs [0023] to [0049], and FIG. 1)

### DISCLOSURE OF INVENTION

### Problem to be Solved by the Invention

Recently, with the growth of data centers or the like to make heavy use of a wide variety of computers such as servers, it has been attempted to make thinner a rack housing electronic devices such as servers. A standard for the size of the rack is set by the Electronic Industries Alliance (EIA), and a minimum unit “1 U (Unit)” of the height of the rack is equal to 1.75 inches (44.45 millimeters).

Here, in electronic devices such as servers, a socket or the like to maintain and replace a central processing unit (CPU) is mounted on a board. For this reason, in a low-profile electronic device such as a server mounted in a rack “1 U” in height (hereinafter, also referred to as “a 1 U server”), the permissible space for a cooling device to cool the CPU is limited to about 25 millimeters in height.

On the other hand, since the related ebullient cooling device adopts a thermosiphon system utilizing the buoyancy of the refrigerant vapor and the gravity of the liquid refrigerant as mentioned above, it is necessary to dispose the condenser above the evaporating portion in the vertical direction. However, when the condenser and the evaporating portion are disposed in the space with about 25 millimeters in height as mentioned above, the circulation of the refrigerant by the gravity is blocked because a sufficient vertical interval cannot be obtained. It becomes difficult, therefore, to obtain the sufficient cooling performance.

In the related ebullient cooling device, the condenser 520 is cooled by the air (AIR) blown by means of a cooling fan 540. But the route of the blow is limited when the related ebullient cooling device is mounted in a low-profile electronic device, and the warm air having absorbed the heat in the condenser 520 results in flowing throughout the electronic device. Consequently, there has been a problem that the cooling efficiency of the entire electronic device decreases.

Thus, there has been a problem that, when the related ebullient cooling device is mounted in a low-profile electronic device, not only is it impossible to obtain the sufficient cooling performance, but also the cooling efficiency of the entire electronic device decreases.

The object of the present invention is to provide a cooling device and an electronic device using the same which solve the problem mentioned above that, when a cooling device employing an ebullient cooling system is mounted in a low-profile electronic device, not only is it impossible to obtain the sufficient cooling performance, but also the cooling efficiency of the entire electronic device decreases.

### Means for Solving a Problem

A cooling device according to an exemplary aspect of the invention includes evaporating means for storing a refrigerant; condensing means for condensing and liquefying a vapor-phase refrigerant vaporized in the evaporation means and radiating heat; a pipe connecting the evaporating means to the condensing means; and flow regulating means for regulating a flow direction of air passing through the condensing means, wherein the evaporating means and the condensing means are located on roughly the same level in the vertical direction; the evaporating means includes an evaporation container and bulkhead means for separating the refrigerant disposed in the evaporation container; the height of the bulkhead means is larger than or equal to the height of a vapor-liquid interface of the refrigerant and is smaller than the height of the evaporation container; the pipe includes a vapor pipe through which vapor-phase refrigerant flows and a liquid pipe through which condensed and liquefied liquid-phase refrigerant flows; the condensing means includes first condensing means and second condensing means which differ in condensing-means height which is defined as the height in vertical direction of a condensation container composing the condensing means, and the condensing-means height of the first condensing means is configured to be larger than the condensing-means height of the second condensing means; the first condensing means includes a vapor pipe connection portion which is connected to the vapor pipe at the position above the condensing-means height of the second condensing means in vertical direction; and the flow regulating means is disposed in the upper part of the second condensing means.

An electronic device according to an exemplary aspect of the invention includes a cooling device; a heating element; and heat radiating means, wherein the cooling device includes evaporating means for storing a refrigerant; condensing means for condensing and liquefying a vapor-phase refrigerant vaporized in the evaporation means and radiating heat; a pipe connecting the evaporating means to the condensing means; and flow regulating means for regulating a flow direction of air passing through the condensing means, wherein the evaporating means and the condensing means are located on roughly the same level in the vertical direction; the evaporating means includes an evaporation container and bulkhead means for separating the refrigerant disposed in the evaporation container; the height of the bulkhead means is larger than or equal to the height of a vapor-liquid interface of the refrigerant and is smaller than the height of the evaporation container; the pipe includes a vapor pipe through which vapor-phase refrigerant flows and a liquid pipe through which condensed and liquefied liquid-phase refrigerant flows; the condensing means includes first condensing means and second condensing means which differ in condensing-means height which is defined as the height in vertical direction of a condensation container composing the condensing means, and the condensing-means height of the first condensing means is configured to be larger than the condensing-means height of the second condensing means; the first condensing means includes a vapor pipe connection portion which is connected to the vapor pipe at the position above the condensing-means height of the second condensing means in vertical direction; and the flow regulating means is disposed in the upper part of the second condensing means; wherein the evaporating means is disposed in the upper part of the heating element and is thermally connected to the heating element, and the condensing means is disposed in the upper part of the heat radiating means and is thermally connected to the heat radiating means.

### Effect of the Invention

According to the cooling device of the present invention, it is possible to obtain a cooling device employing an ebullient cooling system which has the sufficient cooling performance and furthermore can prevent the cooling efficiency of the entire electronic device from decreasing even though it is mounted in a low-profile electronic device.

### BRIEF DESCRIPTION OF THE DRAWINGS

FIG. 1 is a cross-sectional side view illustrating a configuration of a cooling device in accordance with the first exemplary embodiment of the present invention.

FIG. 2 is a diagram illustrating a configuration of a cooling device in accordance with the first exemplary embodiment of the present invention, and is a cross-sectional view taken along the line II-II of FIG. 1.

FIG. 3 is a perspective view illustrating a configuration adjacent to a condenser of a cooling device in accordance with the first exemplary embodiment of the present invention.

FIG. 4 is a top view illustrating a configuration of a cooling device in accordance with the first exemplary embodiment of the present invention.

FIG. 5 is a top view illustrating another configuration of a cooling device in accordance with the first exemplary embodiment of the present invention.

FIG. 6 is a cross-sectional side view illustrating a configuration of a cooling device in accordance with the second exemplary embodiment of the present invention.

FIG. 7 is a cross-sectional side view illustrating a configuration of a cooling device in accordance with the third exemplary embodiment of the present invention.

FIG. 8 is a diagram illustrating a configuration of a cooling device in accordance with the third exemplary embodiment of the present invention, and is a cross-sectional view taken along the line VIII-VIII of FIG. 7.

FIG. 9 is an exploded perspective view illustrating a configuration adjacent to a condenser of a cooling device in accordance with the third exemplary embodiment of the present invention.

FIG. 10 is a diagram illustrating another configuration of a cooling device in accordance with the third exemplary embodiment of the present invention, and is a cross-sectional view taken along the line VIII-VIII of FIG. 7.

FIG. 11 is a cross-sectional side view illustrating a configuration of an electronic device in accordance with the fourth exemplary embodiment of the present invention.

FIG. 12 is a cross-sectional side view illustrating another configuration of an electronic device in accordance with the fourth exemplary embodiment of the present invention.

FIG. 13 is a cross-sectional side view illustrating a configuration of a related ebullient cooling device.

### DESCRIPTION OF EMBODIMENTS

The exemplary embodiments of the present invention will be described with reference to the drawings below.

### The First Exemplary Embodiment

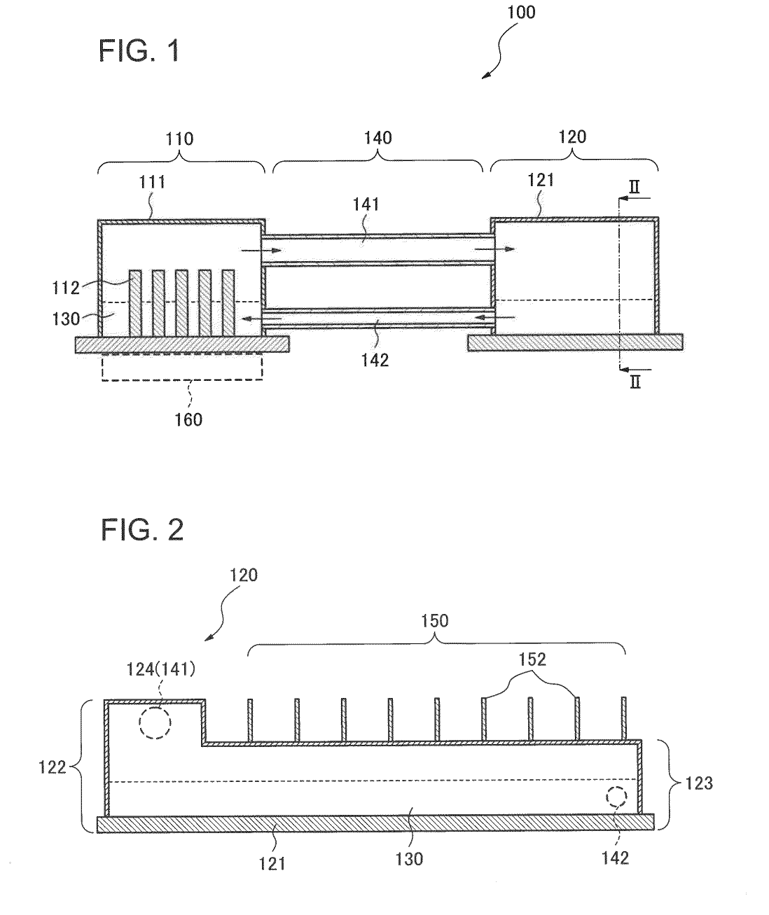

FIG. 1 is a cross-sectional side view illustrating a configuration of a cooling device 100 in accordance with the first exemplary embodiment of the present invention. The cooling device 100 includes an evaporator 110 storing a refrigerant 130, a condenser 120 condensing and liquefying a vapor-phase refrigerant vaporized in the evaporator 110 and radiating heat, and a pipe 140 connecting the evaporator 110 to the condenser 120. It is possible, therefore, to dispose the condenser 120 away from a heating element 160 thermally connected to the evaporator 110. Here, the evaporator 110 and the condenser 120 are located on roughly the same level in the vertical direction. That enables the cooling device 100 to be mounted in a low-profile electronic device with the height of a device restricted.

The evaporator 110 includes an evaporation container 111 and a bulkhead section 112 separating the refrigerant 130 disposed in the evaporation container 111. Here, the height of the bulkhead section 112 is larger than or equal to that of the vapor-liquid interface of the refrigerant 130 and is smaller than that of the evaporation container 111. Here, the vapor-liquid interface of the refrigerant means an interface between the refrigerant in liquid state and the refrigerant in vapor state. The pipe 140 includes a vapor pipe 141 through which vapor-phase refrigerant flows and a liquid pipe 142 through which condensed and liquefied liquid-phase refrigerant flows.

It is possible to keep the pressure within the evaporation container 111 equal to a saturated vapor pressure of the refrigerant 130 constantly by using a low-boiling material as the refrigerant 130 and evacuating the evaporation container 111 after having injected the refrigerant 130 into it. In FIG. 1, a hatched portion in the evaporator 110 and the condenser 120 represents the refrigerant in liquid state, and a dotted line in the hatched portion represents the vapor-liquid interface of the refrigerant 130. It is possible to use as the refrigerant 130 a low-boiling refrigerant such as hydrofluorocarbon and hydrofluoroether which are insulating and inactive materials, for example. As the materials composing the evaporator 110 and the condenser 120, it is possible to use the metal having an excellent thermal conductive property such as aluminum and copper.

Next, a configuration adjacent to the condenser 120 will be described in more detail. FIG. 2 is a cross-sectional view taken along the line II-II of FIG. 1. The condenser 120 includes a first condenser 122 and a second condenser 123 which differ in condenser height which is defined as the height in vertical direction of the condensation container 121 composing the condenser 120. Here, the condenser height of the first condenser 122 is configured to be larger than that of the second condenser 123. The first condenser 122 includes a vapor pipe connection portion 124 which is connected to the vapor pipe 141 at the position above, in vertical direction, the condenser height of the second condenser 123. Moreover, the cooling device 100 according to the present exemplary embodiment includes a flow regulating unit 150 which is disposed on the upper surface of the second condenser 123. The flow regulating unit 150 regulates a flow direction of the air passing through the condenser 120. According to the cooling device 100 configured as described above, it becomes possible to dispose the flow regulating unit 150 securing the volume occupied by the refrigerant in vapor state (refrigerant vapor) in the condenser 120 without increasing the condenser height.

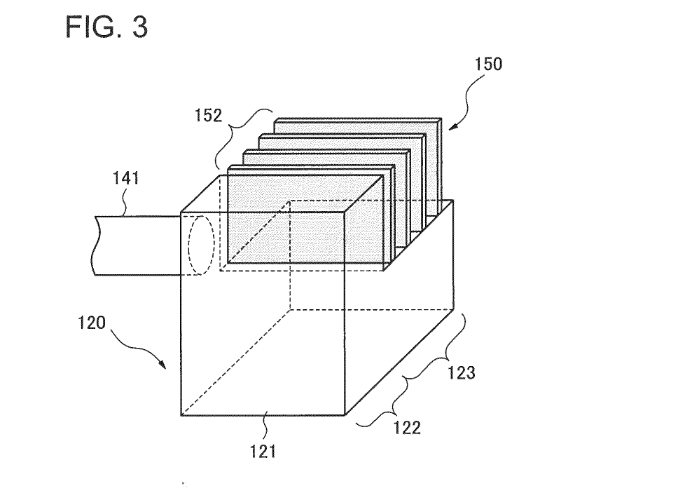

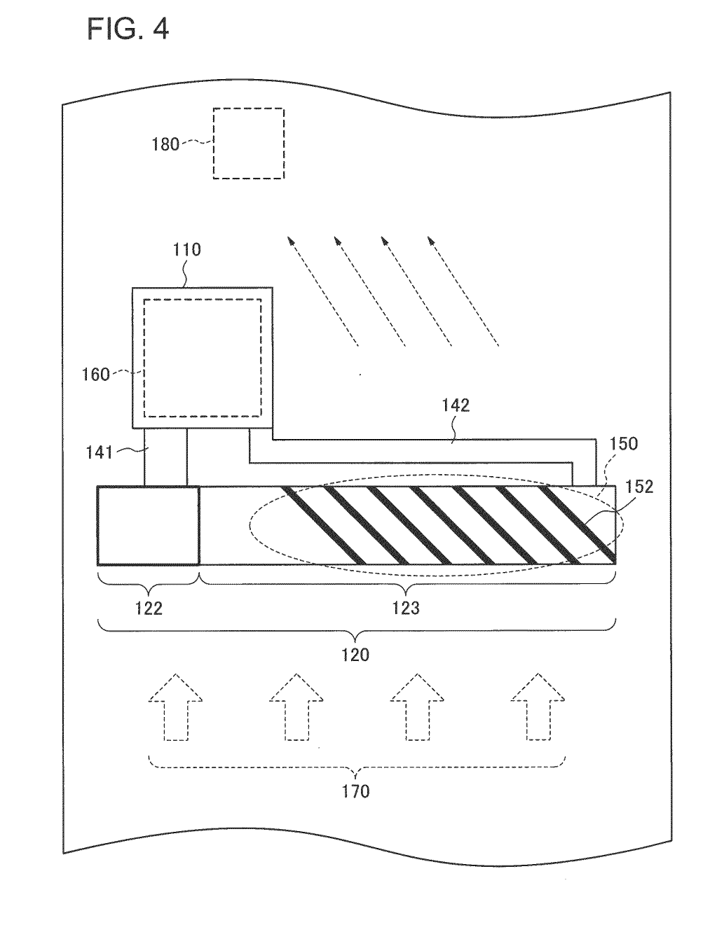

An example of a specific configuration of the flow regulating unit 150 is illustrated in FIGS. 3 and 4. FIG. 3 is a perspective view illustrating a configuration adjacent to the condenser 120 in the cooling device 100 according to the present exemplary embodiment. FIG. 4 is a top view illustrating a configuration of the cooling device 100 according to the present exemplary embodiment. As shown in FIGS. 3 and 4, the flow regulating unit 150 can be configured to include a plurality of flow regulating thin plates 152 with rectangle-shaped thin plates standing. At this time, part of the air (cooling air 170) flowing into the condenser flows along the flow regulating thin plates 152. The cooling air 170 can be configured to be blown by a cooling fan to cool an electronic device in which the cooling device 100 is mounted, for example.

As shown in FIG. 4, the flow regulating thin plates 152 can be disposed so that their drawing directions may be inclined to the inflow direction of the air (cooling air 170) flowing into the condenser 120. This enables to change the flow direction of the cooling air from the direction in which to flow into the condenser 120 to an intended direction. In an example shown in FIG. 4, the flow direction of the cooling air is changed to the direction (dashed-line arrows in FIG. 4) toward a heat generating component 180 which is disposed in downstream direction diagonally behind the cooling device 100. Although this enables part of the cooling air 170 to absorb heat passing through the condenser 120 and to flow reaching a state of warm air, the other part of the cooling air 170 which has passed through the flow regulating unit 150 reaches the heat generating component 180 with it holding cool. It is possible, therefore, to cool efficiently also the heat generating component 180 composing the electronic device. The examples of the heat generating component 180 include a CPU peripheral element (chip set) with its permissible temperature range (temperature margin) small.

As described above, according to the cooling device 100 in the present exemplary embodiment, the heating element 160 thermally connected to the evaporator 110 is cooled by radiating the heat in the condenser 120. And it becomes possible to cool another heat generating component 180 which is mounted in the electronic device by the cooling air whose flow direction is controlled by the flow regulating unit 150. That is to say, according to the present exemplary embodiment, it is possible to obtain the cooling device 100 which has the sufficient cooling performance and furthermore can prevent the cooling efficiency of the entire electronic device from decreasing even though it is mounted in a low-profile electronic device.

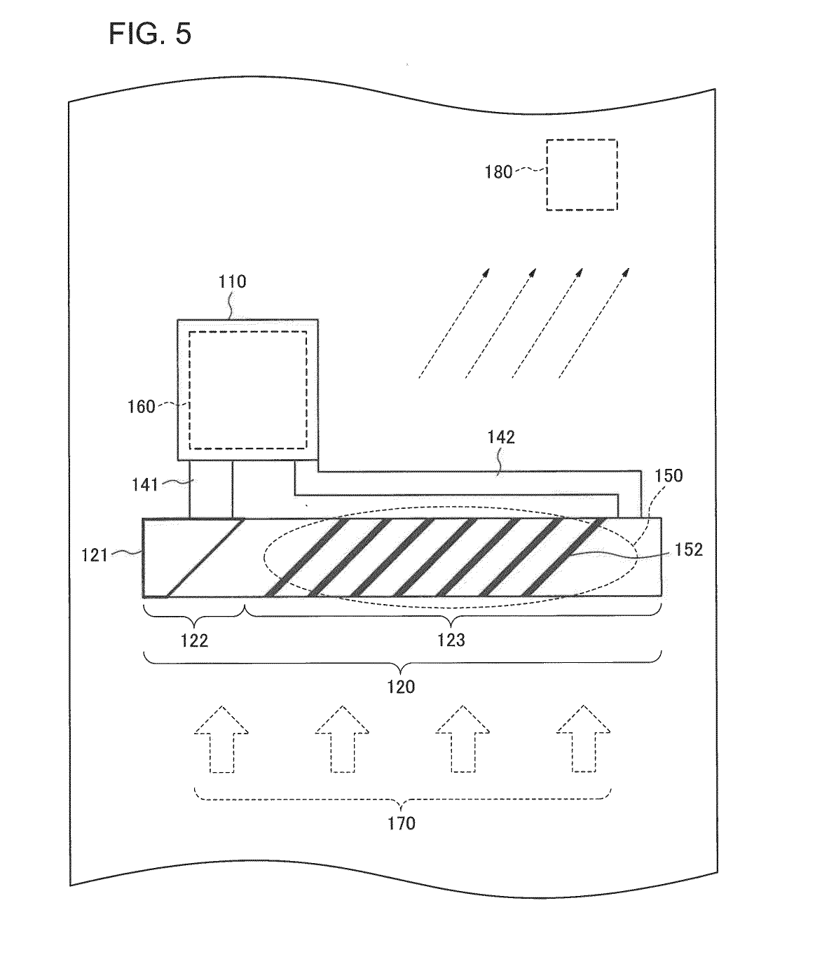

The configuration of the flow regulating unit 150 is not limited to that shown in FIG. 4, and it is possible to configure the flow regulating thin plates 152 so that the cooling air can flow in a direction toward the location where the heat generating component 180 is disposed. At this time, as shown in FIG. 5, it is also acceptable that the side surface of the condensation container 121 at the boundary region between the first condenser 122 and the second condenser 123 is configured to be inclined to the inflow direction of the air flowing into the condenser 120. This further accelerates the flow of the cooling air in a direction toward the location where a heat generating component is disposed.

Next, the operation of the cooling device 100 in accordance with the present exemplary embodiment will be described in detail. As shown in FIG. 1, the cooling device 100 is used disposing the heating element 160 such as a central processing unit (CPU) at the bottom of the evaporator 110, thermally connected to the evaporator 110. It is possible to obtain a good thermal connection by mounting the evaporator 110 and the heating element 160 through a heat-conducting material such as grease. The heat from the heating element is conducted to the refrigerant 130 through the evaporation container 111 of the evaporator 110, so that the refrigerant 130 vaporizes. At this time, since the heat from the heating element is drawn by the refrigerant as vaporization heat, the increase in temperature of the heating element is suppressed.

The injected amount of the refrigerant 130 is determined so that it may be larger than or equal to the amount calculated from the amount of heat generation of the heating element 160 and the vaporization heat of the refrigerant and that the height of the vapor-liquid interface of the refrigerant 130 may be shorter than or equal to the height of the bulkhead section 112.

The height of the bulkhead section 112 can be set so that a space between about 5 and 10 millimeters in height may be disposed between the upper edge of the bulkhead section 112 and the top board of the evaporation container 111.

The refrigerant vapor evaporated in the evaporator 110 expands in volume from liquid phase and fills the evaporation container 111, and a pressure difference occurs within the evaporation container 111 due to the presence of the bulkhead section 112. That is to say, since the height of the bulkhead section 112 is larger than or equal to the height of the vapor-liquid interface of the refrigerant 130, there exists the refrigerant vapor also in the area of the bulkhead section 112. In the area of the bulkhead section 112, however, the volume of the refrigerant vapor is limited because the refrigerant vapor is separated by the bulkhead section 112. Therefore, the pressure of the refrigerant vapor in the area of the bulkhead section 112 is larger than that in the area between the upper edge of the bulkhead section 112 and the top board of the evaporation container 111. Here, the bulkhead section 112 can be configured to include a plurality of bulkhead thin plates (fins) with rectangle-shaped thin plates standing. At this time, the volume occupied by the refrigerant vapor in the area of the bulkhead section 112 is limited due to spacing between the bulkhead thin plates (fins).

On the other hand, in the condenser 120, the refrigerant vapor is cooled due to contact with the condensation container 121 and the like and is condensed and liquefied. Since the refrigerant vapor rapidly reduces the volume with a phase-change into liquid, the pressure of vapor-phase refrigerant within the condensation container 121 becomes lower than that within the evaporation container 111. Consequently, the pressure gradient of the refrigerant vapor occurs among the bulkhead section 112 of the evaporator 110, the area between the upper edge of the bulkhead section 112 and the top board of the evaporation container 111, and the condensation container 121, in this order. According to the cooling device 100 of the present exemplary embodiment, therefore, since the evaporator 110 and the condenser 120 are located on roughly the same level in the vertical direction, it becomes possible to transport the refrigerant vapor from the evaporator 110 to the condenser 120 even though the circulation of the refrigerant vapor by buoyancy is unavailable.

The vapor-liquid interface of the refrigerant in the evaporator 110 lowers because the liquid-phase refrigerant vaporizes and breaks away turning into bubbles in the evaporator 110. However, the liquid-phase refrigerant is immediately supplied to the evaporator 110 from the condenser 120 through the liquid pipe 142 so that the vapor-liquid interface of the refrigerant in the evaporator 110 and the condenser 120 can be kept constant. This enables the liquid-phase refrigerant to circulate between the evaporator 110 and the condenser 120 even though the circulation of the liquid-phase refrigerant by the gravity is unavailable because the evaporator 110 and the condenser 120 are located on roughly the same level in the vertical direction.

As described above, the pipe 140 is configured to include the vapor pipe 141 through which the vapor-phase refrigerant flows and the liquid pipe 142 through which the liquid-phase refrigerant condensed and liquefied flows. It is preferable that the vapor pipe 141 should be configured to be connected to the evaporation container 111 at the position higher than or equal to the height of the bulkhead section 112. It is preferable that the liquid pipe 142 should be configured to be connected to each of the evaporation container 111 and the condensation container 121 at the position lower than or equal to the height of the vapor-liquid interface of the refrigerant. Such a configuration makes it possible to accelerate the circulation of refrigerant.

As mentioned above, according to the cooling device 100 of the present exemplary embodiment, it is possible to obtain a cooling device employing an ebullient cooling system which has the sufficient cooling performance even though it is necessary to dispose the evaporator 110 and the condenser 120 on roughly the same level in the vertical direction, for example, even though mounted in a low-profile electronic device.

### The Second Exemplary Embodiment

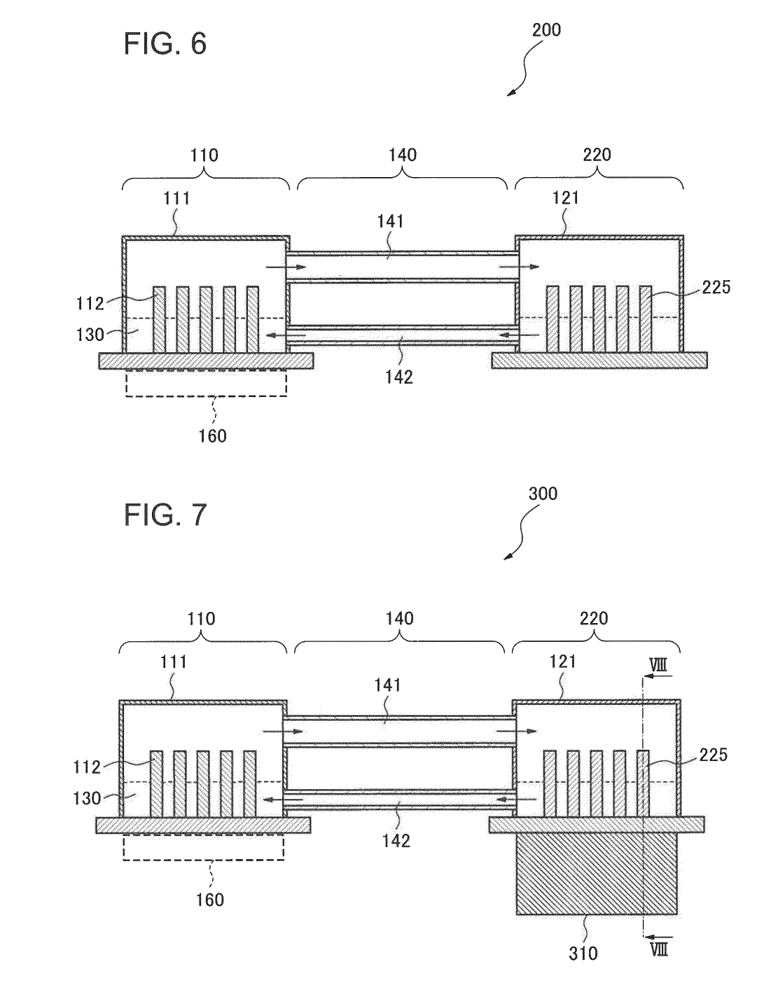

Next, the second exemplary embodiment of the present invention will be described. FIG. 6 is a cross-sectional side view illustrating a configuration of a cooling device 200 in accordance with the second exemplary embodiment of the present invention. The cooling device 200 includes the evaporator 110 storing the refrigerant 130, a condenser 220 condensing and liquefying a vapor-phase refrigerant vaporized in the evaporator 110 and radiating heat, and a pipe 140 connecting the evaporator 110 to the condenser 220. Here, the evaporator 110 and the condenser 220 are located on roughly the same level in the vertical direction. The evaporator 110 includes the evaporation container 111 and a bulkhead section 112 separating the refrigerant 130 disposed in the evaporation container 111, and the height of the bulkhead section 112 is larger than or equal to that of the vapor-liquid interface of the refrigerant 130 and is smaller than that of the evaporation container 111. The pipe 140 includes the vapor pipe 141 through which vapor-phase refrigerant flows and a liquid pipe 142 through which condensed and liquefied liquid-phase refrigerant flows.

The condenser 220 includes the first condenser 122 and the second condenser 123 which differ in the condenser height which is defined as the height in vertical direction of the condensation container 121 composing the condenser 220. Here, the condenser height of the first condenser 122 is configured to be larger than that of the second condenser 123. The first condenser 122 includes the vapor pipe connection portion 124 which is connected to the vapor pipe 141 at the position above, in vertical direction, the condenser height of the second condenser 123. Moreover, the cooling device 200 according to the present exemplary embodiment includes the flow regulating unit 150 which is disposed on the upper surface of the second condenser 123. The flow regulating unit 150 regulates a flow direction of the air passing through the condenser 220.

The cooling device 200 according to the present exemplary embodiment differs from the cooling device 100 of the first exemplary embodiment in the configuration of the condenser 220, and the other configurations are the same, and therefore, the detailed description about them is omitted. The condenser 220 includes a condensing plate unit 225 accelerating the heat radiation of vapor-phase refrigerant in the condensation container 121. Since the condensing plate unit 225 accelerates cooling, condensing and liquefying the refrigerant vapor in the condenser 220, it is possible to further improve the cooling performance of the cooling device 200.

In order to condense and liquefy efficiently the refrigerant vapor generated in the evaporator 110 by the condensing plate unit 225, it is preferable that the condensing plate unit 225 should have a large surface area. The condensing plate unit 225, therefore, can be configured to include a plurality of condensing thin plates (fins) with rectangle-shaped thin plates standing. In order to dispose the condensing plate unit 225 not only in the first condenser 122 but also in the second condenser 123, it is preferable that the height of the condensing plate unit 225 should be configured to be lower than the condenser height of the second condenser 123.

As mentioned above, according to the cooling device 200 of the present exemplary embodiment, since the condensing plate unit 225 disposed within the condensation container 121 accelerates cooling, condensing and liquefying the refrigerant vapor, it is possible to further improve the cooling performance. And it becomes possible to cool another heat generating component 180 which is mounted in the electronic device by the cooling air whose flow direction is controlled by the flow regulating unit 150. That is to say, according to the present exemplary embodiment, it is possible to obtain the cooling device 200 which has the sufficient cooling performance and furthermore can prevent the cooling efficiency of the entire electronic device from decreasing even though it is mounted in a low-profile electronic device.

### The Third Exemplary Embodiment

Next, the third exemplary embodiment according to the present invention will be described. FIG. 7 is a cross-sectional side view illustrating a configuration of a cooling device 300 according to the third exemplary embodiment of the present invention. The cooling device 300 includes the evaporator 110 storing the refrigerant 130, the condenser 220 condensing and liquefying a vapor-phase refrigerant vaporized in the evaporator 110 and radiating he at, and a pipe 140 connecting the evaporator 110 to the condenser 220. Here, the evaporator 110 and the condenser 220 are located on roughly the same level in the vertical direction. The evaporator 110 includes the evaporation container 111 and a bulkhead section 112 separating the refrigerant 130 disposed in the evaporation container 111, and the height of the bulkhead section 112 is larger than or equal to that of the vapor-liquid interface of the refrigerant 130 and is smaller than that of the evaporation container 111. The condenser 220 is configured to include the condensing plate unit 225 accelerating the heat radiation of vapor-phase refrigerant within the condensation container 121. The pipe 140 includes the vapor pipe 141 through which vapor-phase refrigerant flows and a liquid pipe 142 through which condensed and liquefied liquid-phase refrigerant flows.

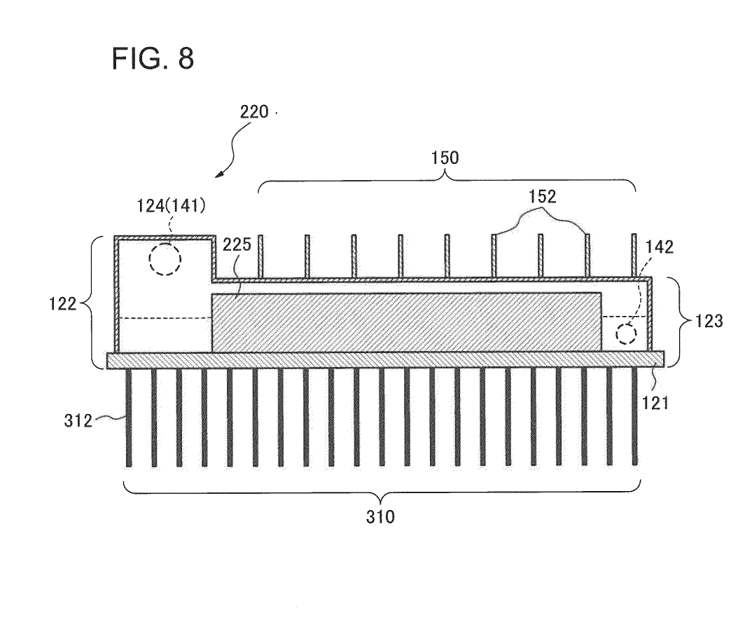

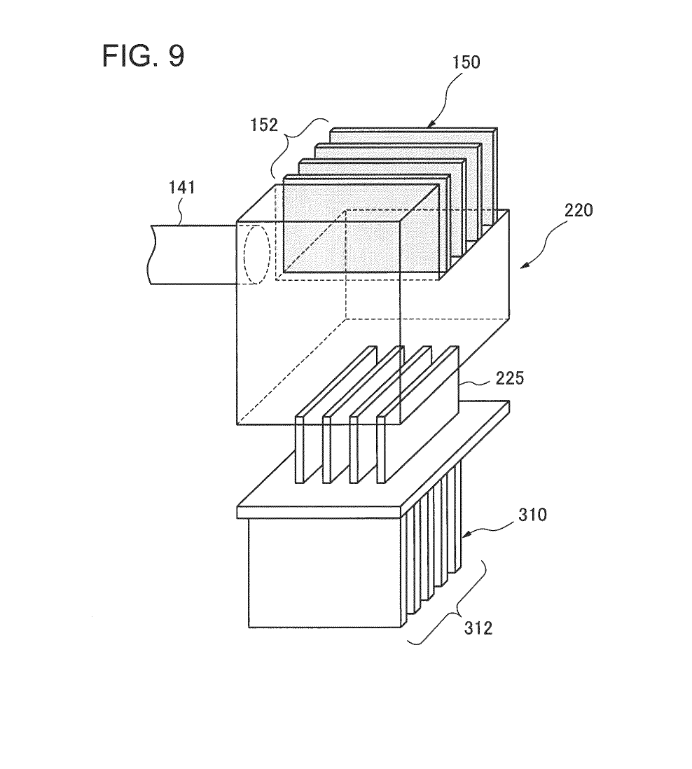

Next, a configuration adjacent to the condenser 220 will be described in more detail. FIG. 8 is a cross-sectional view taken along the line VIII-VIII of FIG. 7. FIG. 9 is an exploded perspective view illustrating a configuration adjacent to the condenser 220 of the cooling device 300 according to the present exemplary embodiment.

The condenser 220 includes the first condenser 122 and the second condenser 123 which differ in the condenser height which is defined as the height in vertical direction of the condensation container 121 composing the condenser 220. Here, the condenser height of the first condenser 122 is configured to be larger than that of the second condenser 123. The first condenser 122 includes the vapor pipe connection portion 124 which is connected to the vapor pipe 141 at the position above, in vertical direction, the condenser height of the second condenser 123. Moreover, the cooling device 300 includes the flow regulating unit 150 which is disposed on the upper surface of the second condenser 123. The flow regulating unit 150 includes a plurality of flow regulating thin plates 152 with rectangle-shaped thin plates standing and regulates a flow direction of the air passing through the condenser 220. In the present exemplary embodiment, the condenser 220 is configured to include the condensing plate unit 225 accelerating the heat radiation of vapor-phase refrigerant within the condensation container 121.

The cooling device 300 according to the present exemplary embodiment differs from the cooling device 200 according to the second exemplary embodiment in further including a heat radiating unit 310 thermally connected to the condenser 220. The other configurations are the same as those in the second exemplary embodiment, and therefore, the detailed description about them is omitted here. As shown in FIGS. 8 and FIG. 9, the heat radiating unit 310 is disposed at the bottom of the condenser 220 and can be configured to include a plurality of heat radiating thin plates 312 with rectangle-shaped thin plates standing. The heat radiating thin plate 312 typically has a fin shape, and can be formed by using the metal having an excellent thermal conductive property such as aluminum and copper. The heat radiating unit 310 and the condensing plate unit 225 can be formed as a unit, or can be thermally connected to each other after having been formed independently.

Here, the cooling device 300 according to the present exemplary embodiment can be configured so that a distance between every two adjacent ones of the flow regulating thin plates 152 may be larger than a distance between every two adjacent ones of the heat radiating thin plates 312. By this configuration, the plurality of flow regulating thin plates 152 and the plurality of heat radiating thin plates 312 can effectively fulfill their respective functions that the plurality of flow regulating thin plates 152 control a flow direction of the air passing through the condenser 220 and that the plurality of heat radiating thin plates 312 accelerating cooling the refrigerant vapor in the condenser 220. Specifically, for example, the distance of the flow regulating thin plates 152 is about 7 millimeters, and the distance of the heat radiating thin plates 312 is about 2 millimeters.

By this heat radiating unit 310, cooling, condensing and liquefying of refrigerant vapor in the condenser 220 are accelerated, and thus, it is possible to further improve the cooling performance of the cooling device 300. Moreover, according to the cooling device 300 of the present exemplary embodiment, even though the evaporator 110 and the condenser 220 are configured to be located on roughly the same level in the vertical direction, it is possible to circulate the refrigerant. Therefore, the heat radiating unit 310 can be disposed at the bottom of the condenser 220 which is located at the same side as that of the heating element 160. Accordingly, it is unnecessary to ensure another area in order to install the heat radiating unit 310, and therefore, it becomes possible to mount the cooling device 300 in a low-profile electronic device.

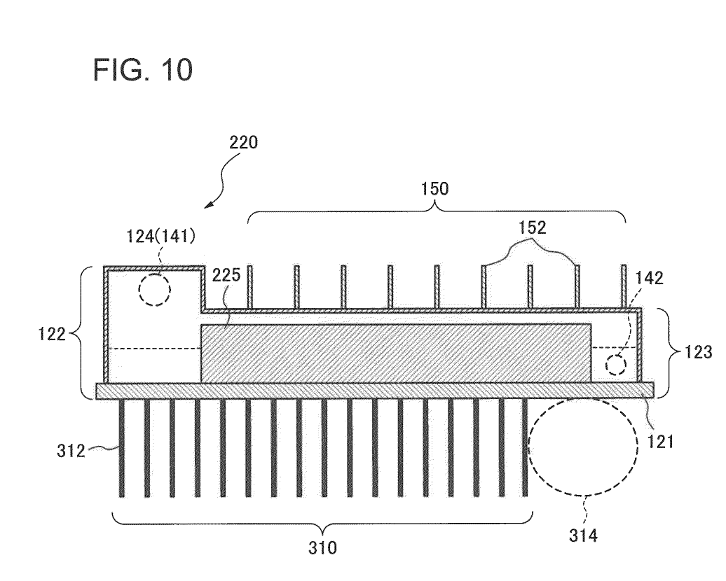

In addition, in FIG. 8, there is illustrated a case where, as the configuration of the heat radiating unit 310, the heat radiating thin plates 312 are disposed across the entire area below the condenser 220. However, it is not limited to this, the heat radiating unit 310 can be also configured to include a blower area 314 where any of the heat radiating thin plates 312 is not disposed. For example, as shown in FIG. 10, the configuration can be made so that the blower area 314, in which any of the heat radiating thin plates 312 is not disposed, is included in an area neighboring a position connected to the liquid pipe 142. In the blower area 314, cooling air 170 passes through a vicinity of the heat radiating unit 310 with it holding cool without receiving heat from the heat radiating thin plates 312. Thus, it becomes also possible to cool heat generating components existing on an extension of a flow direction of cooling air. That is to say, heat generating components existing on an extension of a flow direction of cooling air are not cooled by cooling air whose flow direction is controlled by the flow regulating unit 150, but are cooled by part of the cooling air 170 which passes through the blower area 314.

As described above, according to the cooling device 300 of the present exemplary embodiment, the heat radiating unit 310, which is thermally connected to the condenser 220, accelerates cooling as well as condensing and liquefying of refrigerant vapor, and therefore, it is possible to further improve the cooling performance. And it becomes possible to cool other heat generating components which are mounted in an electronic device by using cooling air whose flow direction is controlled by the flow regulating unit 150. That is to say, according to the cooling device 300 of the present exemplary embodiment it is possible to realize a cooling device which has the sufficient cooling performance and furthermore can prevent the cooling efficiency of the entire electronic device from decreasing even though it is mounted in a low-profile electronic device.

### The Fourth Exemplary Embodiment

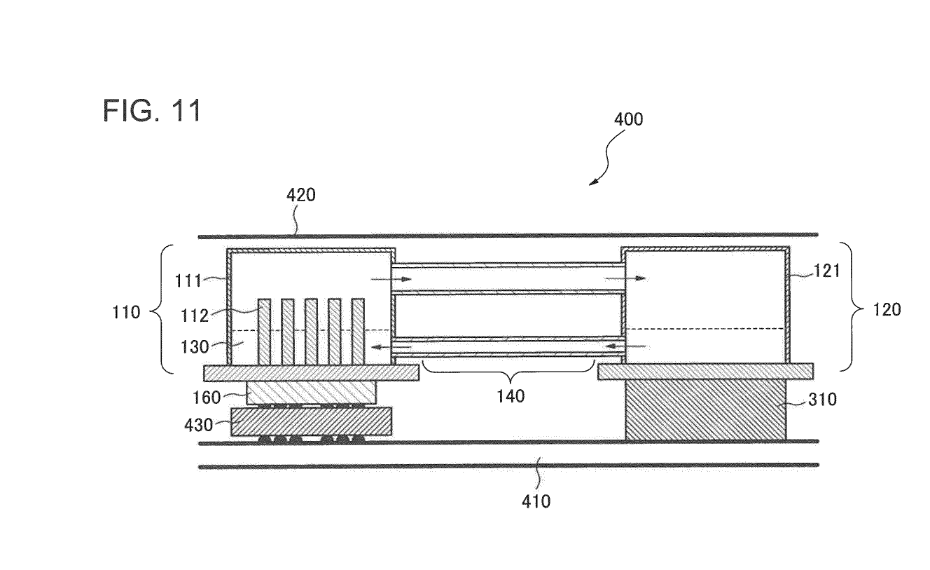

Next, the fourth exemplary embodiment according to the present invention will be described. FIG. 11 is a cross-sectional side view illustrating a configuration of an electronic device 400 according to the fourth exemplary embodiment of the present invention. The electronic device 400 includes a cooling device, a heating element 160, and a heat radiating unit 310. The configuration of this cooling device is the same as that of the cooling device 100 according to the first exemplary embodiment. That is to say, the cooling device 100 includes an evaporator 110 storing refrigerant 130, a condenser 120 in which heat radiation is performed by condensing and liquefying vapor-phase refrigerant evaporated by the evaporator 110, a pipe 140 connecting between the evaporator 110 and the condenser 120, and a flow regulating unit 150 regulating a flow direction of air passing through the condenser 120. Here, the evaporator 110 and the condenser 120 are located on roughly the same level in the vertical direction. The evaporator 110 includes an evaporation container 111 and a bulkhead section 112 separating the refrigerant 130 contained in the evaporation container 111, and the height of the bulkhead section 112 is larger than or equal to the height of the vapor-liquid interface of the refrigerant 130 and is smaller than the height of the evaporation container 111. The pipe 140 includes a vapor pipe through which vapor-phase refrigerant flows and a liquid pipe through which condensed and liquefied liquid-phase refrigerant flows.

The condenser 120 includes a first condenser and a second condenser which differ in condenser height which is defined as the height in vertical direction of the condensation container composing the condenser 120, and the condenser height of the first condenser is configured to be higher than the condenser height of the second condenser. The first condenser includes a vapor pipe connection portion connected to the vapor pipe at the position above, in vertical direction, the condenser height of the second condenser. Here, the flow regulating unit 150 is disposed at a position above the second condenser.

In the electronic device 400 according to the present exemplary embodiment, the evaporator 110 is disposed at a position above the heating element 160 so as to be thermally connected thereto, and the condenser 120 is disposed at a position above the heat radiating unit 310 so as to be thermally connected thereto.

The electronic device 400 is, for example, a server or the like including a central processing unit (CPU) as the heating element 160, and is disposed on a substrate 410 and is installed in a chassis 420. The heat generating 160, such as a CPU, is mounted on the substrate 410 in the state being loaded into a socket 430 or the like. The evaporator 110 is mounted at a position above the heating element 160 via a heat conduction member therebetween, such as grease. Meanwhile, the condenser 120 connected to the evaporator 110 via the pipe 140 is disposed together with the heat radiating unit 310 at a position distanced from the heating element 160. Further, heat from the heating element 160 is thermally transported in conjunction with the movement of the refrigerant 130 as a vapor-liquid two phase flow, so that the heating element 160 is cooled. And it becomes possible to cool other heat generating components mounted in the electronic device by using cooling air whose flow direction is controlled by the flow regulating unit 150.

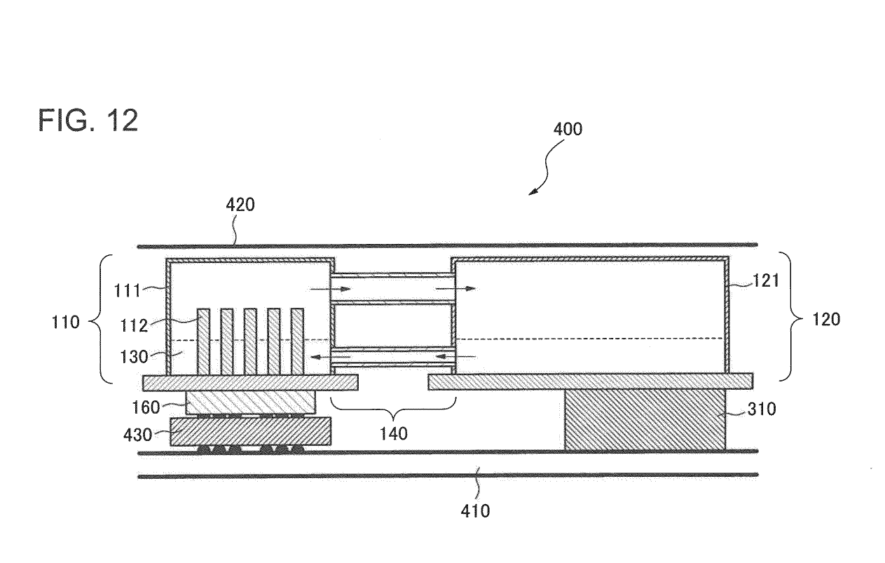

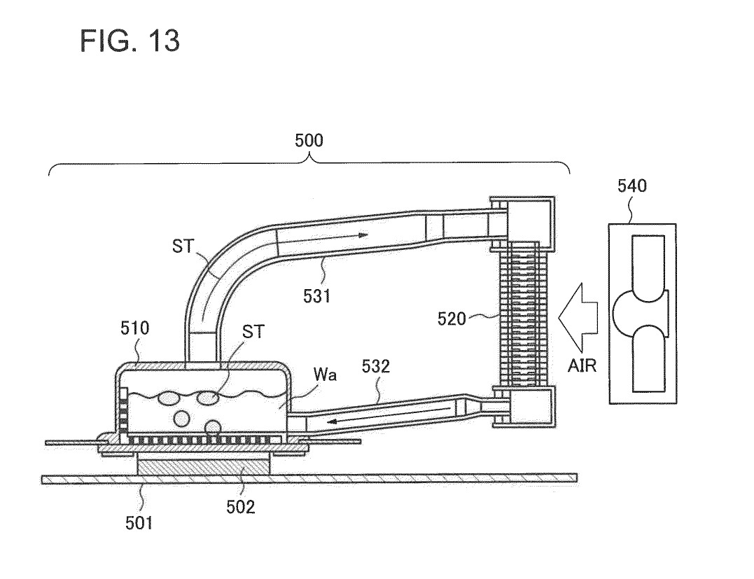

FIG. 11 illustrates the configuration in which the condenser 120 and the heat radiating unit 310 have substantially the same width. However, the configuration of the electronic device 400 is not limited to this, and may be made such that, for example, as shown in FIG. 12, the width of the condenser 120 is extended in a direction towards the evaporator 110. In this way, since the capacity of the condenser 120 is increased, the volume of vapor-phase refrigerant is also increased. As a result, the elevation of a boiling point of the refrigerant due to the increase of internal pressure of the cooling device 100 is eased, and thereby, the suppression of vaporization of liquid-phase refrigerant in the evaporator 110 can be prevented. Thus, it becomes possible to realize further improvement of the cooling performance of the cooling device 100.

As described above, according to the electronic device 400 of the present exemplary embodiment, it is possible to, when the evaporator 110 and the condenser 120 are disposed at positions of substantially the same height in a vertical direction, realize a cooling device employing an ebullient cooling method, which is superior in a heat transportation capability. Thus, even when, for example, a target electronic device is a low-profile electronic device adapted to a rack having a height of 1 U (44.45 millimeters), it is possible to achieve the sufficient cooling performance. Moreover, it is possible to prevent the degradation of a cooling efficiency of the entire electronic device.

The present invention is not limited to the aforementioned embodiments. Various modifications can be made therein within the scope of the present invention as defined by the claims, and obviously, such modifications are included in the scope of the present invention.

This application is based upon and claims the benefit of priority from Japanese Patent Application No. 2012-000039, filed on Jan. 4, 2012, the disclosure of which is incorporated herein in its entirety by reference.

### DESCRIPTION OF THE CODES

100, 200, 300 cooling device

110 evaporator

111 evaporation container

112 bulkhead section

120, 220 condenser

121 condensation container

122 first condenser

123 second condenser

124 vapor pipe connection portion

130 refrigerant

140 pipe

141 vapor pipe

142 liquid pipe

150 flow regulating unit

152 flow regulating thin plate

160 heating element

170 cooling air

180 heat generating component

225 condensing plate unit

310 heat radiating unit

312 heat radiating thin plate

314 blower area

400 electronic device

410 substrate

420 chassis

430 socket

500 related ebullient cooling device

501 circuit board

502 semiconductor device

510 evaporating portion

520 condenser

531 vapor conduit

532 liquid return conduit

540 cooling fan

1. A cooling device, comprising:
an evaporator for storing a refrigerant;
a condenser for condensing and liquefying a vapor-phase refrigerant vaporized in the evaporator and radiating heat;
a pipe connecting the evaporator to the condenser; and
a flow regulating unit regulating a flow direction of air passing through the condenser,
wherein the evaporator and the condenser are located on roughly the same level in the vertical direction;
the evaporator comprises an evaporation container and a bulkhead section separating the refrigerant disposed in the evaporation container;
the height of the bulkhead section is larger than or equal to the height of a vapor-liquid interface of the refrigerant and is smaller than the height of the evaporation container;
the pipe comprises a vapor pipe through which vapor-phase refrigerant flows and a liquid pipe through which condensed and liquefied liquid-phase refrigerant flows;
the condenser comprises a first condenser and a second condenser which differ in condenser height which is defined as the height in vertical direction of a condensation container composing the condenser, and the condenser height of the first condenser is configured to be larger than the condenser height of the second condenser;
the first condenser comprises a vapor pipe connection portion which is connected to the vapor pipe at the position above the condenser height of the second condenser in vertical direction; and
the flow regulating unit is disposed in the upper part of the second condenser.

2. The cooling device according to claim 1,
wherein the flow regulating unit comprises a plurality of flow regulating thin plates with rectangle-shaped thin plates standing, and
a drawing direction of the flow regulating thin plates is inclined to an inflow direction of air flowing into the condenser.

3. The cooling device according to claim 1,
wherein the vapor pipe is connected to the evaporation container at a position higher than or equal to the height of the bulkhead section, and
the liquid pipe is connected to the evaporation container at a position lower than or equal to the height of the vapor-liquid interface of the refrigerant.

4. The cooling device according to claim 1,
wherein the bulkhead section comprises a plurality of bulkhead thin plates with rectangle-shaped thin plates standing.

5. The cooling device according to claim 1,
wherein the condenser comprises a condensing plate unit accelerating heat radiation of the vapor-phase refrigerant in the condensation container;
the condensing plate unit comprises a plurality of condensing thin plates with rectangle-shaped thin plates standing; and
the height of the condensing plate unit is lower than the condenser height of the second condenser.

6. The cooling device according to claim 1,
wherein the liquid pipe is connected to the condensation container at a position lower than or equal to the height of the vapor-liquid interface of the refrigerant.

7. The cooling device according to claim 1, further comprising a heat radiating unit thermally connected to the condenser,
wherein the heat radiating unit is disposed in the lower part of the condenser.

8. The cooling device according to claim 7,
wherein the flow regulating unit comprises a plurality of flow regulating thin plates with rectangle-shaped thin plates standing,
the heat radiating unit comprises a plurality of heat radiating thin plates with rectangle-shaped thin plates standing; and
a distance between the flow regulating thin plates is larger than a distance between the heat radiating thin plates.

9. The cooling device according to claim 1,
wherein a side surface of the condensation container at a boundary region between the first condenser and the second condenser is inclined to the inflow direction of air flowing into the condenser.

10. An electronic device, comprising:
a cooling device;
a heating element; and
a heat radiating unit,
wherein the cooling device comprises
an evaporator storing a refrigerant;
a condenser condensing and liquefying a vapor-phase refrigerant vaporized in the evaporator and radiating heat;
a pipe connecting the evaporator to the condenser; and
a flow regulating unit regulating a flow direction of air passing through the condenser,
wherein the evaporator and the condenser are located on roughly the same level in the vertical direction;
the evaporator comprises an evaporation container and a bulkhead section for separating the refrigerant disposed in the evaporation container;
the height of the bulkhead section is larger than or equal to the height of a vapor-liquid interface of the refrigerant and is smaller than the height of the evaporation container;
the pipe comprises a vapor pipe through which vapor-phase refrigerant flows and a liquid pipe through which condensed and liquefied liquid-phase refrigerant flows;
the condenser comprises a first condenser and a second condenser which differ in condenser height which is defined as the height in vertical direction of a condensation container composing the condenser, and the condenser height of the first condenser is configured to be larger than the condenser height of the second condenser;
the first condenser comprises a vapor pipe connection portion which is connected to the vapor pipe at the position above the condenser height of the second condenser in vertical direction; and
the flow regulating unit is disposed in the upper part of the second condenser;
wherein the evaporator is disposed in the upper part of the heating element and is thermally connected to the heating element, and
the condenser is disposed in the upper part of the heat radiating unit and is thermally connected to the heat radiating unit.

11. A cooling device, comprising:
evaporating means for storing a refrigerant;
condensing means for condensing and liquefying a vapor-phase refrigerant vaporized in the evaporation means and radiating heat;
a pipe connecting the evaporating means to the condensing means; and
flow regulating means for regulating a flow direction of air passing through the condensing means,
wherein the evaporating means and the condensing means are located on roughly the same level in the vertical direction;
the evaporating means comprises an evaporation container and bulkhead means for separating the refrigerant disposed in the evaporation container;
the height of the bulkhead means is larger than or equal to the height of a vapor-liquid interface of the refrigerant and is smaller than the height of the evaporation container;
the pipe comprises a vapor pipe through which vapor-phase refrigerant flows and a liquid pipe through which condensed and liquefied liquid-phase refrigerant flows;
the condensing means comprises first condensing means and second condensing means which differ in condensing-means height which is defined as the height in vertical direction of a condensation container composing the condensing means, and the condensing-means height of the first condensing means is configured to be larger than the condensing-means height of the second condensing means;
the first condensing means comprises a vapor pipe connection portion which is connected to the vapor pipe at the position above the condensing-means height of the second condensing means in vertical direction; and
the flow regulating means is disposed in the upper part of the second condensing means.

12. The cooling device according to claim 2,
wherein the vapor pipe is connected to the evaporation container at a position higher than or equal to the height of the bulkhead section, and
the liquid pipe is connected to the evaporation container at a position lower than or equal to the height of the vapor-liquid interface of the refrigerant.

13. The cooling device according to claim 2,
wherein the bulkhead section comprises a plurality of bulkhead thin plates with rectangle-shaped thin plates standing.

14. The cooling device according to claim 2,
wherein the condenser comprises a condensing plate unit accelerating heat radiation of the vapor-phase refrigerant in the condensation container;
the condensing plate unit comprises a plurality of condensing thin plates with rectangle-shaped thin plates standing; and
the height of the condensing plate unit is lower than the condenser height of the second condenser.

15. The cooling device according to claim 2,
wherein the liquid pipe is connected to the condensation container at a position lower than or equal to the height of the vapor-liquid interface of the refrigerant.

16. The cooling device according to claim 2, further comprising a heat radiating unit thermally connected to the condenser,
wherein the heat radiating unit is disposed in the lower part of the condenser.

17. The cooling device according to claim 16,
wherein the flow regulating unit comprises a plurality of flow regulating thin plates with rectangle-shaped thin plates standing,
the heat radiating unit comprises a plurality of heat radiating thin plates with rectangle-shaped thin plates standing; and
a distance between the flow regulating thin plates is larger than a distance between the heat radiating thin plates.

18. The cooling device according to claim 2,
wherein a side surface of the condensation container at a boundary region between the first condenser and the second condenser is inclined to the inflow direction of air flowing into the condenser.
